(19) United States
(12) Patent Application Publication
(10) Pub. No.: US 2026/0027671 A1
(43) Pub. Date: Jan. 29, 2026

(54) POLISHING APPARATUS

(71) Applicant: EBARA CORPORATION, Tokyo (JP)

(72) Inventors: Ryota YAMAOKA, Tokyo (JP); Nozomu KUWABARA, Tokyo (JP); Yukihiro KANG, Tokyo (JP); Yasuyuki MOTOSHIMA, Tokyo (JP); Shumpei MIURA, Tokyo (JP); Seiya HIGUCHI, Tokyo (JP)

(21) Appl. No.: 19/273,728

(22) Filed: Jul. 18, 2025

(30) Foreign Application Priority Data
Jul. 25, 2024 (JP) 2024-119211

(51) Int. Cl. B24B 37/015; B24B 57/02

(52) U.S. Cl. CPC B24B 37/015; B24B 57/02

(57) ABSTRACT

A polishing apparatus is disclosed, which can precisely control a polishing rate by quickly decreasing a pad temperature to below ambient temperature. The polishing apparatus includes a rotatable polishing table supporting a polishing pad; a polishing head configured to press a substrate W against a polishing surface of the rotating polishing pad to polish the substrate; at least one pad-temperature measuring device configured to measuring a temperature of the polishing surface; a pad-temperature regulating apparatus for regulating the temperature of the polishing surface; and a controller configured to control operation of the pad-temperature regulating apparatus based on the temperature of the polishing surface measured by the at least one pad-temperature measuring device. The pad-temperature regulating apparatus includes: at least one cooling nozzle configured to inject a cooling agent onto the polishing surface; and at least one gas nozzle configured to inject dry gas onto the polishing surface. The cooling agent has a boiling point lower than atmosphere temperature.

### CROSS REFERENCE TO RELATED APPLICATION

This document claims priority to Japanese Patent Application No. 2024-filed Jul. 25, 2024, the entire contents of which are hereby incorporated by reference.

### BACKGROUND

CMP (Chemical Mechanical Polishing) apparatus is used in a process of polishing a surface of a substrate in a semiconductor device fabrication. The CMP apparatus is configured to hold and rotate the substrate with a polishing head, and press the substrate against a polishing pad on a rotating polishing table to polish the surface of the substrate. During polishing, a polishing liquid (e.g., slurry) is supplied onto the polishing pad, so that the surface of the substrate is planarized by the chemical action of the polishing liquid and the mechanical action of abrasive particles contained in the polishing liquid.

A polishing rate of substrate depends not only on a polishing load on the substrate pressed against the polishing pad, but also on a surface temperature of the polishing pad (i.e., a temperature of polishing surface). This is because the chemical action of the polishing liquid with respect to the substrate depends on temperature. Accordingly, in the semiconductor device fabrication, it is very important to maintain the surface temperature of the polishing pad at an optimum value during polishing of the substrate in order to increase and further keep constant the polishing rate of the substrate. In this specification, the surface temperature of the polishing pad may be referred to as the “pad temperature”.

From this viewpoint, a pad-temperature regulating apparatus has been conventionally used to regulate the pad temperature (see Japanese laid-open patent publication No. 2022-170648, for example). The pad-temperature regulating apparatus described in Japanese laid-open patent publication No. 2022-170648 includes a pad-heater configured to inject a heating fluid onto the surface of the polishing pad, and a pad-cooler configured to inject a cooling fluid onto the surface of the polishing pad. A flow rate of the heating fluid supplied onto the pad-heater and a flow rate of the cooling fluid supplied onto the pad-cooler are regulated, respectively, so that the pad temperature during polishing of the substrate can be controlled and maintained at a desired temperature.

### SUMMARY

In general, the polishing rate of the substrate decreases as the pad temperature decreases, since the chemical action of the polishing liquid with respect to the substrate depends on temperature. In contrast, depending on the type of polishing pad, a hardness of the polishing pad may increase as the pad temperature decreases, resulting in an increase in the polishing rate.

For this reason, in recent years, there has been a demand for decreasing the pad temperature to a temperature (e.g., 0° C.) lower than ambient temperature (e.g., atmosphere temperature around the polishing pad) in order to control the polishing rate more precisely and improve the in-plane uniformity of the substrate after polishing. Further, for the same reason, users of polishing apparatus may have also a demand for quickly decreasing the pad temperature, which has been increased to a high temperature, to a target temperature.

Therefore, there is provided a polishing apparatus capable of precisely controlling the polishing rate by quickly decreasing the pad temperature to below ambient temperature.

Embodiments, which will be described below, relate to a polishing apparatus for polishing a substrate, such as a semiconductor wafer, by bringing the substrate into sliding contact with a polishing pad, and more particularly relates to a polishing apparatus for polishing a substrate while regulating a temperature of a surface of the polishing pad.

In one embodiment, there is a polishing apparatus including: a rotatable polishing table supporting a polishing pad; a polishing head configured to press a substrate against a polishing surface of the rotating polishing pad to polish the substrate; at least one pad-temperature measuring device configured to measuring a temperature of the polishing surface; a pad-temperature regulating apparatus for regulating the temperature of the polishing surface; and a controller configured to control operation of the pad-temperature regulating apparatus based on the temperature of the polishing surface measured by the at least one pad-temperature measuring device, wherein the pad-temperature regulating apparatus includes: at least one cooling nozzle configured to inject a cooling agent onto the polishing surface; and at least one gas nozzle configured to inject dry gas onto the polishing surface, and the cooling agent has a boiling point lower than atmosphere temperature.

In one embodiment, the cooling nozzle is placed between the polishing head and the gas nozzle as viewed in a rotational direction of the polishing table.

In one embodiment, the at least one cooling nozzle comprises a plurality of cooling nozzles arranged in correspondence with each of a plurality of regions divided in a radial direction of the polishing table, and the controller controls a flow rate of the cooling agent supplied to each cooling nozzle to thereby independently regulate the temperature of each of the plural regions.

In one embodiment, the at least one pad-temperature measuring device comprises a plurality of pad-temperature measuring devices that can measure the temperatures of the plurality of regions, respectively.

In one embodiment, the pad-temperature regulating apparatus further includes a heater configured to heat the polishing surface, and the heater is placed between the polishing head and the at least one cooling nozzle, as viewed in a rotational direction of the polishing table.

In one embodiment, the cooling agent is dry ice.

The cooling agent having boiling point lower than atmosphere temperature is used to decrease the pad temperature, so that the substrate can be polished at pad temperature lower than the atmosphere temperature. Accordingly, the polishing apparatus can polish the substrate while regulating the pad temperature in a wider temperature control range than that of the conventional polishing apparatus. Further, the pad temperature can be quickly decreased, thereby enabling the substrate to be polished more precisely than with conventional polishing apparatus, and improving the in-plane uniformity of the substrate after polishing.

### BRIEF DESCRIPTION OF THE DRAWINGS

FIG. 1 is a schematic view showing a polishing apparatus according to one embodiment;

FIG. 2 is a schematic view showing a cooler according to one embodiment;

FIG. 3 is a schematic view showing a gas injector according to one embodiment;

FIG. 4 is a schematic view showing an example of the arrangement of the cooling nozzles and the gas nozzles according to one embodiment;

FIG. 5 is a schematic view showing the pressure gas containing the cooling agent, which is injected from the cooling nozzles;

FIG. 6A is a schematic view showing a cooling nozzle according to another embodiment;

FIG. 6B is a schematic cross-sectional view of the cooling nozzle shown in FIG. 6A;

FIG. 7 is a schematic view showing a heater according to one embodiment;

FIG. 8 is a schematic view showing an example of a position adjustment mechanism for adjusting an inclination and a height of the cooling nozzle relative to the polishing pad;

FIG. 9 is a schematic view showing another example of the position adjustment mechanism; and

FIG. 10 is a schematic view showing a common nozzle formed integrally with the heating nozzle of the heater, the cooling nozzle of the cooler, and the gas nozzle of the gas injector.

### DESCRIPTION OF EMBODIMENTS

Hereinafter, embodiments will be described with reference to the drawings.

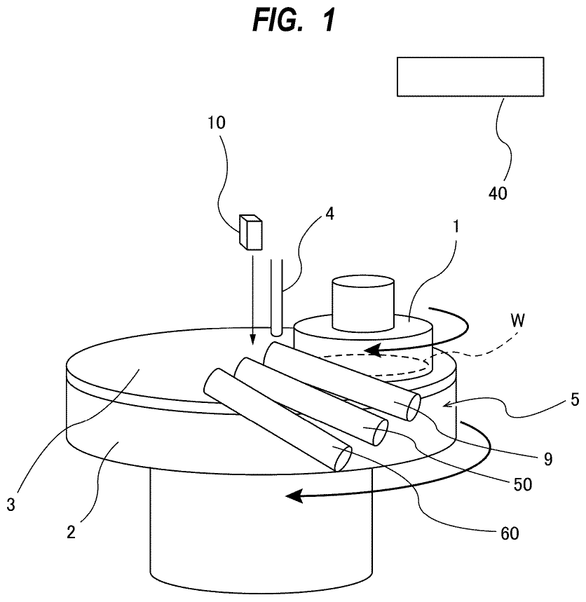

FIG. 1 is a schematic view showing a polishing apparatus according to one embodiment. The polishing apparatus shown in FIG. 1 includes a polishing head 1 for holding and rotating a wafer W which is an example of a substrate, a polishing table 2 that supports a polishing pad 3, a polishing-liquid supply nozzle 4 for supplying a polishing liquid (e.g. a slurry) onto a surface of the polishing pad 3, a pad-temperature measuring device 10 for measuring a surface temperature of the polishing pad 3, and a pad-temperature regulating apparatus 5 for regulating the surface temperature of the polishing pad 3. The surface (upper surface) of the polishing pad 3 provides a polishing surface for polishing the wafer W.

Further, the polishing apparatus has a controller 40 configured to control operations of the pad-temperature regulating apparatus 5 based on the temperature of the polishing surface of the polishing pad 3 (i.e., “pad temperature”) measured by the pad-temperature measuring device 10. In this embodiment, the controller 40 is configured to control operations of the polishing apparatus in its entirety, including the pad-temperature regulating apparatus 5.

The polishing head 1 is vertically movable, and is rotatable about its axis in a direction indicated by arrow. The wafer W is held on a lower surface of the polishing head 1 by, for example, vacuum suction. A motor (not shown) is coupled to the polishing table 2, so that the polishing table 2 can rotate in a direction indicated by arrow. As shown in FIG. 1, the polishing head 1 and the polishing table 2 rotate in the same direction. The polishing pad 3 is attached to an upper surface of the polishing table 2.

Polishing of the wafer W is performed in the following manner. The wafer W, to be polished, is held by the polishing head 1, and is then rotated by the polishing head 1. The polishing pad 3 is rotated together with the polishing table 2. In this state, the polishing liquid is supplied from the polishing-liquid supply nozzle 4 onto the surface of the polishing pad 3, and the surface of the wafer W is then pressed by the polishing head 1 against the surface (i.e. polishing surface) of the polishing pad 3. The surface of the wafer W is polished by the sliding contact with the polishing pad 3 in the presence of the polishing liquid. The surface of the wafer W is planarized by the chemical action of the polishing liquid and the mechanical action of abrasive grains contained in the polishing liquid.

The pad-temperature regulating apparatus 5 shown in FIG. 1 includes a cooler 50 for injecting a cooling agent onto the polishing surface of the polishing pad 3 to cool the polishing surface, and a gas injector 60 for injecting dry gas onto the polishing surface. The cooler 50 includes at least one cooling nozzle disposed above the polishing pad 3, and the cooling agent is injected from the cooling nozzle. Configuration of the cooler 50 will be described later.

The cooling agent is a material used to decrease the pad temperature, and has a boiling point lower than atmosphere temperature. In this specification, atmosphere temperature corresponds to a temperature around the polishing table 2 and/or the polishing pad 3, unless otherwise specified. Examples of cooling agent may include solids that sublimate at normal temperature and normal pressure, such as dry ice, and liquids, such as liquefied gases (e.g., liquid nitrogen, liquid oxygen, liquid helium, liquefied carbon dioxide, and liquid hydrogen). However, the type of cooling agent is not limited to these examples. The state of the cooling agent may be any of liquid, solid, or gas, as long as the cooling agent has a boiling point lower than atmosphere temperature. In this embodiment, dry ice, which is solidified carbon dioxide, is used as the cooling agent. Dry ice has, at normal temperature and normal pressure, a boiling point (sublimation point) of −78.5° C. and is a material that sublimates directly into a gas. In addition, dry ice is a relatively inexpensive material that is readily available on the market.

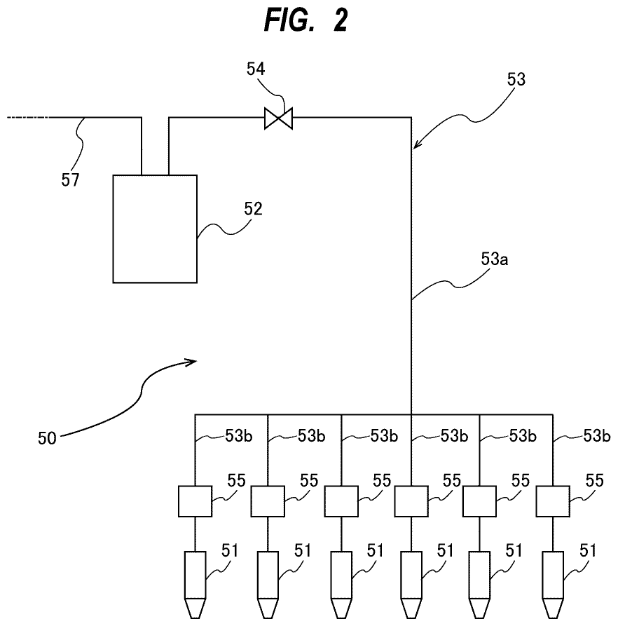

FIG. 2 is a schematic view showing a cooler according to one embodiment. The cooler 50 shown in FIG. 2 includes a plurality of (six in FIG. 2) cooling nozzles 51, a cooling-agent source 52, a cooling-agent line 53 coupling the cooling nozzles 51 with the cooling-agent source 52, a main valve 54 disposed in the cooling-agent line 53, a cooling-agent flow regulator 55 disposed in the cooling-agent line 53, and a pressure line 57 coupled to the cooling-agent source 52.

The cooling-agent source 52 is a container, such as a cylinder, for storing the cooling agent described above, for example. The pressure line 57 is a line through which a gas (hereinafter referred to as pressure gas) having a predetermined pressure is flowed, and the pressure gas causes the cooling agent stored in the cooling-agent source 52 to be transported to the cooling nozzles 51 through the cooling-agent line 53. The pressure gas containing the cooling agent is injected from each of the cooling nozzles 51. The type of pressure gas can be freely selected as long as the pressure gas enables the cooling agent to be transported to the cooling nozzles 51. However, the pressure gas is preferably an inert gas, such as nitrogen, argon, or helium, so as not to deteriorate the cooling agent and the polishing liquid, and so as not to adversely affect devices formed on the wafer W.

The cooling-agent line 53 is composed of a cooling-agent main line 53a coupled to the cooling-agent source 52, and cooling-agent branch lines 53b branching from the cooling-agent main line 53a and extending to each cooling nozzle 51. The main valve 54 is disposed in the cooling-agent main line 53a, and the cooling-agent flow regulators 55 are disposed in each of the cooling agent branch lines 53b.

The main valve 54 and the cooling-agent flow regulators 55 are coupled to the controller 40 (see FIG. 1), and the controller 40 is configured to control operations of the main valve 54 and the cooling-agent flow regulators 55. Each of the cooling-agent flow regulators 55 is configured to be able to regulate a flow rate of the pressure gas containing the cooling agent, which is injected from a tip of the cooling nozzle 51. In this specification, the pressure gas containing the cooling agent may be simply referred to as “cooling agent”, and the flow rate of the pressure gas containing the cooling agent may be simply referred to as “cooling-agent flow rate”.

The cooling-agent flow regulator 55 may be a mass flow controller, or may be composed of a combination of an electro-pneumatic regulator and a flow meter. In the case where the cooling-agent flow regulator 55 is composed of the combination of the electro-pneumatic regulator and the flow meter, the controller 40 controls operation of the electro-pneumatic regulator based on measurement values of the flow meter, thereby regulating the pressure of the pressure gas containing cooling agent flowing through the cooling-agent branch line 53b. Changing the pressure of the pressure gas flowing through the cooling-agent branch line 53b enables the flow rate of the pressure gas containing the cooling-agent, which is injected from the cooling nozzle 51, to be changed.

In the illustrated embodiment, the plurality of cooling-agent flow regulators 55 is disposed in the cooling-agent branch lines 53b. However, one cooling-agent flow regulator 55 may be disposed in the cooling-agent main line 53a. In this case, the controller 40 controls the flow rate of the pressure gas containing the cooling-agent which flows through the cooling-agent main line 53a to thereby regulate the flow rate of the cooling-agent injected from each cooling nozzle 51 in a collective manner.

The cooling nozzle 51 is configured to inject granular dry ice as the cooling agent together with the pressure gas from the tip thereof. In this embodiment, the cooling-agent line 53 has heat insulation property so as to prevent the dry ice from completely vaporizing or liquefying in the middle of the cooling-agent line 53. The cooling-agent flow regulator 55 is configured to be able to measure and regulate the flow rate of the pressure gas containing the granular cooling agent. The cooling nozzle 51, the cooling-agent line 53, and the cooling-agent flow regulator 55 having such configurations are commercially available, and dry ice particles having a particle diameter of, for example, 0.1 to 200 μm are injected together with the pressure gas from the cooling nozzle 51.

The cooling agent is injected from the cooling nozzles 51 of the cooler 50 during polishing of the wafer W. The cooling agent injected from the cooling nozzles 51 first causes the polishing liquid on the polishing pad 3 to be cooled. Further, a portion of the cooling agent that has passed through the polishing liquid and reached the polishing surface of the polishing pad 3 causes the polishing surface to be cooled directly. In other words, the cooling agent can quickly decrease the pad temperature indirectly through the polishing liquid and also by direct contact. As a result, the pad temperature can be efficiently decreased. Further, in this embodiment, the cooling agent is dry ice having a boiling point of 0° C. or below, thus enabling the pad temperature to be quickly decreased to a temperature of 0° C. or below.

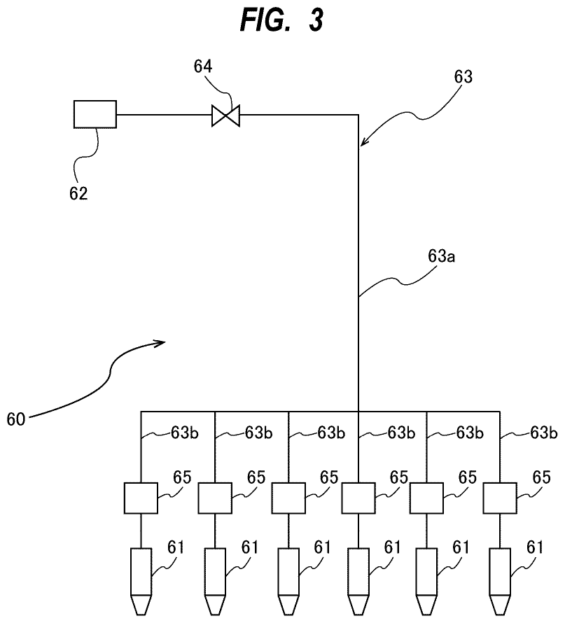

FIG. 3 is a schematic view showing a gas injector according to one embodiment. In the embodiment shown in FIG. 3, the gas injector 60 includes a plurality of dry-gas nozzles 61 (six in FIG. 3) for injecting dry gas onto the polishing surface, a dry-gas source 62, a dry-gas line 63 coupling the dry-gas nozzles 61 with the dry-gas source 62, a dry-gas main valve 64 disposed in the dry-gas line 63, and a dry-gas flow regulator 65 disposed in the dry-gas line 63.

The dry gas is a gas having a humidity lower than that of the atmosphere around the polishing table 2 and/or the polishing pad 3. In order to prevent the cooling agent and the polishing liquid from deteriorating and further to prevent adverse effects on the device formed on the wafer W, the dry gas is preferably an inert gas, such as nitrogen, argon, and helium. Alternatively, the dry gas may be dry air. The dry gas source 62 is, for example, a utility line in a factory where the polishing apparatus is installed.

The dry-gas line 63 is composed of a dry-gas main line 63a coupled to the dry-gas source 62, and dry-gas branch lines 63b branching from the dry-gas main line 63a and extending to each dry-gas nozzle 61. The dry-gas main valve 64 is disposed in the dry-gas main line 63a, and the dry-gas flow regulators 65 are disposed in each of the dry-gas branch lines 63b.

The dry-gas main valve 64 and the dry-gas flow regulators 65 are coupled to the controller 40 (see FIG. 1), and the controller 40 is configured to control operations of the dry-gas main valve 64 and the dry-gas flow regulators 65. Each of the dry-gas flow regulators 65 is configured to be able to regulate a flow rate of the dry gas, which is injected from a tip of the dry-gas nozzle 61. The dry-gas flow regulators 65 may be a mass flow controller, or may be composed of a combination of an electro-pneumatic regulator and a flow meter. In the case where the dry-gas flow regulators 65 is composed of the combination of the electro-pneumatic regulator and the flow meter, the controller 40 controls operation of the electro-pneumatic regulator based on measurement values of the flow meter, thereby regulating the pressure of the dry gas flowing through the dry-gas branch line 63b. Changing the pressure of the dry gas flowing through the dry-gas branch line 63b enables the flow rate of the dry gas, which is injected from the dry-gas nozzle 61, to be changed.

In the illustrated embodiment, the plurality of dry-gas flow regulators 65 is disposed in the dry-gas branch line 63b. However, one dry-gas flow regulator 65 may be disposed in the dry-gas main line 63a. In this case, the controller 40 controls the flow rate of the dry gas which flows through the dry-gas main line 63a to thereby regulate the flow rate of the dry gas injected from each dry-gas nozzle 61 in a collective manner.

The dry gas serves as a gas for preventing the cooling agent injected from the cooling nozzles 51 onto the polishing pad 3 from reaching, due to the rotation of the polishing table 2, the polishing head 1, or in other words, the wafer W during polishing. If the granular cooling agent reaches the wafer W during polishing, the granular cooling agent may become trapped between the wafer W and the polishing pad 3, thereby damaging the devices formed on the wafer W. When the cooling agent is in liquid state, there is a risk that the cooling agent may adversely affect the devices formed on the wafer W. Therefore, the dry gas increases a speed at which the cooling agent is vaporized (hereinafter may be referred to as “vaporization speed”, simply) to prevent the cooling agent from reaching the wafer W during polishing.

Injecting the dry gas onto the polishing pad 3 causes gas layer of the vaporized cooling agent existing around the cooling agent to be blown away, thereby increasing the vaporization speed of the cooling agent. Here, the cooling agent injected onto the polishing pad 3 has a very low temperature because that cooling agent is surrounded by the vapor layer of the vaporized cooling agent. Therefore, blowing away the vapor layer of the vaporized cooling agent existing around the cooling agent enables a temperature around the cooling agent to be increased. From this viewpoint also, the vaporization speed of the cooling agent can be increased. Further, the vaporization speed of the cooling agent can be increased by the presence of dry gas with low humidity around the cooling agent. The flow rate of the dry gas injected from the dry-gas nozzles 61 is regulated to be sufficient to vaporize the cooling agent quickly enough such that the cooling agent does not reach the polishing head 1.

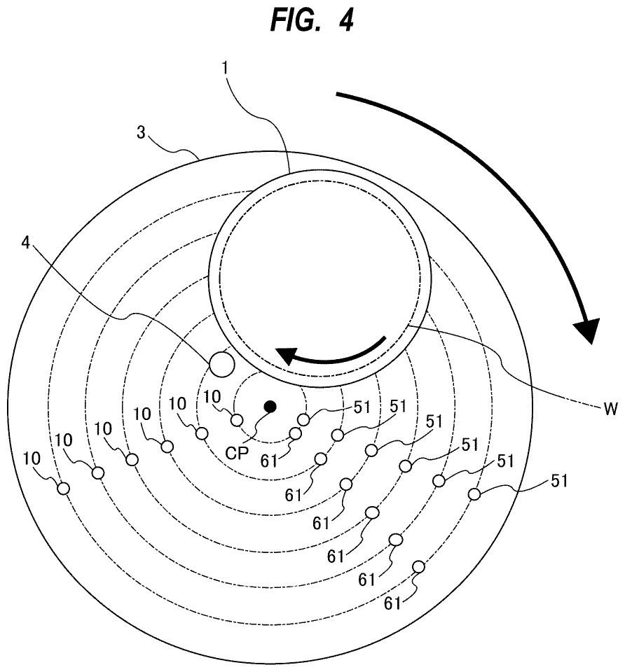

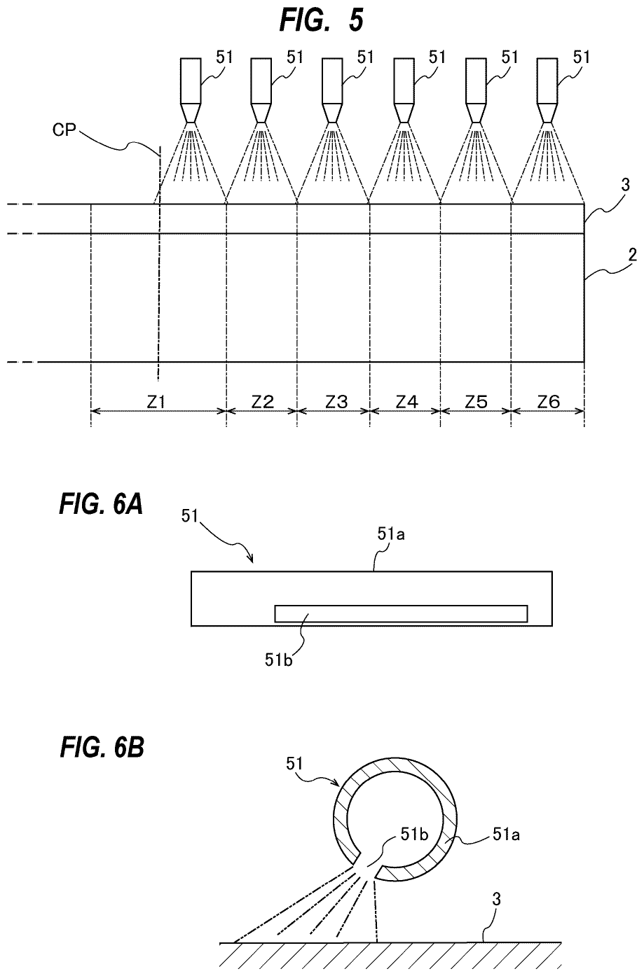

FIG. 4 is a schematic view showing an example of the arrangement of the cooling nozzles and the gas nozzles according to one embodiment. FIG. 5 is a schematic view showing the pressure gas containing the cooling agent, which is injected from the cooling nozzles. FIG. 4 corresponds to a view of the polishing pad 3 from above, and FIG. 5 corresponds to a view of the polishing pad 3 from the side.

As shown in FIG. 4, the plurality of cooling nozzles 51 are arranged in a straight line in a radial direction of the polishing pad 3. As shown in FIG. 5, the plurality of cooling nozzles 51 is arranged such that the pressure gases injected from the plurality of cooling nozzles 51 come into contact with entire range from the center line CP to an outer peripheral edge of the polishing pad 3. The plurality of cooling nozzles 51 are each responsible for cooling a plurality of regions Z1-Z6 of the polishing pad 3 (see FIG. 5). The plurality of regions Z1-Z6 is virtual regions, respectively, which are set corresponding to the plurality of cooling nozzles 51 and are set concentrically. The region Z1 located most centrally is a circular region. Such an arrangement of the plurality of cooling nozzles 51 enables the polishing pad 3 in its entirety to be cooled.

Although not shown, as long as the polishing pad 3 in its entirety can be cooled by the cooling agent injected from the plurality of cooling nozzles 51, the plurality of cooling nozzles 51 need not be arranged in the straight line in the radial direction of the polishing pad 3.

Further, as long as the polishing pad 3 in its entirety can be cooled by the cooling agent injected from the plurality of cooling nozzles 51, the number of cooling nozzles 51 can be freely selected. For example, as shown in FIG. 6A and FIG. 6B, the pad-temperature regulating apparatus 5 may have a single cooling nozzle 51, which has an elongated portion 51a extending in the approximate radial direction of the polishing pad 3, and an injection port 51b for injecting a cooling agent toward the polishing surface of the polishing pad 3. In this case, the injection port 51b has a slit shape formed along a longitudinal direction of the elongated portion 51a, and the injection port 51b is formed so as to come the cooling agent into contact with the entire range from the center CP to the outer peripheral edge of the polishing pad 3 (see FIGS. 4 and 5).

In this embodiment, the dry-gas nozzles 61 are arranged corresponding to the cooling nozzles 51 (see FIG. 4). More specifically, the plurality of dry-gas nozzles 61 are arranged corresponding to the plurality of regions Z1-Z6 of the polishing pad 3, and are arranged in a straight line in the radial direction of the polishing pad 3. As long as the cooling agent injected from the cooling nozzles 51 can be prevented from reaching the polishing head 1, the plurality of dry-gas nozzles 61 need not be arranged in the straight line in the radial direction of the polishing pad 3. Further, as long as the cooling agent injected from the cooling nozzles 51 can be prevented from reaching the polishing head 1, the number of dry-gas nozzles 61 can be freely selected. Although not shown, like the cooling nozzle 51 described with reference to FIG. 6A and FIG. 6B, the pad-temperature regulating apparatus 5 may have a single dry gas nozzle 61 having an elongated portion extending in the approximate radial direction of the polishing pad 3 and an injection port for injecting the dry gas toward the polishing surface of the polishing pad 3.

As shown in FIG. 4, the cooling nozzles 51 are disposed between the polishing head 1 and the plurality of dry-gas nozzles 61 as viewed in a rotational direction of the polishing table 2 (i.e., the polishing pad 3). In other words, the cooling nozzles 51 are placed upstream of the gas injector 60 having the plurality of dry-gas nozzles 61 in the rotational direction of the polishing table 2, and downstream of the polishing head 1 in the rotational direction of the polishing table 2. Arranging the cooling nozzles 51 and the dry-gas nozzles 61 in this manner prevents a portion of the cooling agent injected from the cooling nozzles 51 from being blown away by the dry gas injected from the dry-gas nozzles 61, thereby enabling the cooling agent to exhibit the desired cooling performance and the dry gas to exhibit the desired vaporization performance.

The polishing apparatus may have one pad-temperature measuring device 10 as shown in FIG. 1, or may have a plurality of pad-temperature measuring devices 10, corresponding to the number of regions Z1-Z6, as shown in FIG. 4. In other words, the polishing apparatus may have at least one pad-temperature measuring device 10. The pad-temperature measuring device 10 is disposed between the gas injector 60 and the polishing head 1 as viewed in the rotational direction of the polishing table 2. In other words, the pad-temperature measuring device 10 is placed upstream with respect to the polishing head 1 in the rotational direction of the polishing table 2 and downstream with respect to the gas injector 60 in the rotational direction of the polishing table 2.

The pad-temperature measuring device 10 is configured to measure the pad surface temperature in a non-contact manner, and sends the measurement values to the controller 40. The pad-temperature measuring device 10 may be an infrared thermometer or thermocouple thermometer which measures the surface temperature of the polishing pad 3, and may be a temperature distribution measuring device which acquires the temperature distribution (temperature profile) of the polishing pad 3 in a radial direction of the polishing pad 3. Examples of the temperature distribution measuring device may include thermography, thermopile, and infrared cameras. When the polishing apparatus has single pad-temperature measuring device 10, the pad-temperature measuring device 10 is configured to measure the distribution of the surface temperature of the polishing pad 3 in a region including the center and the outer peripheral edge of the polishing pad 3 and a region extending in the radial direction of the polishing pad 3. In this specification, the temperature distribution (temperature profile) indicates a relationship between the pad surface temperature and the radial position on the wafer W. The controller 40 can acquire each of pad temperatures in the plurality of regions Z1-Z6 on the polishing pad 3 from the measurement values of the pad temperature measuring device 10.

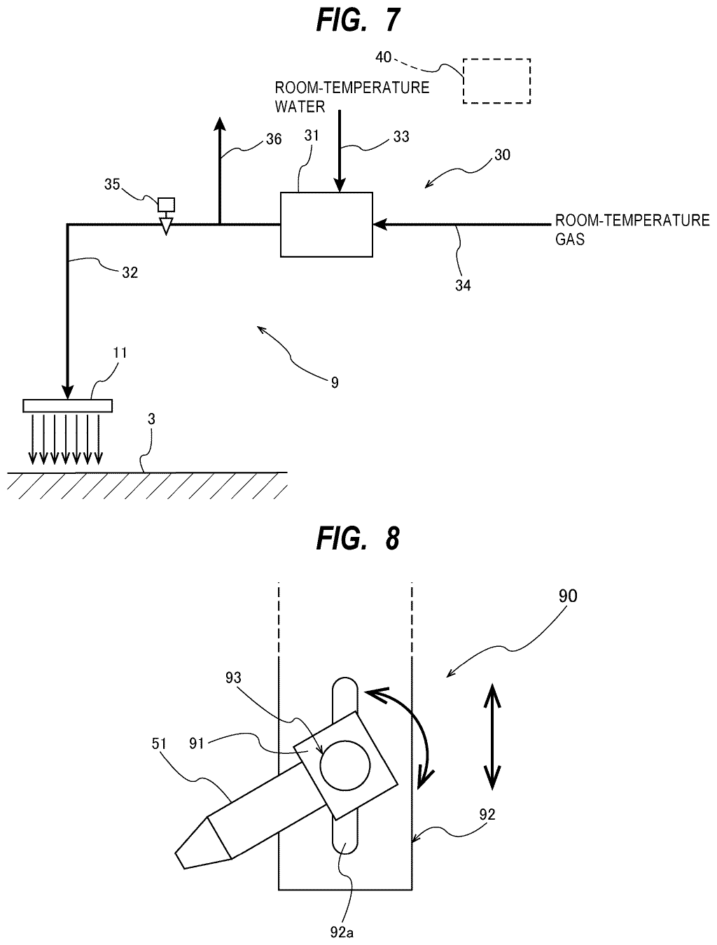

Returning to FIG. 1, the polishing apparatus according to this embodiment has a heater 9 for heating the polishing surface of the polishing pad 3. FIG. 7 is a schematic view showing a heater according to one embodiment. The heater 9 shown in FIG. 7 includes at least a heating nozzle 11 disposed above the polishing pad 3, and a heating-fluid supply system 30 for supplying heating fluid to the heating nozzle 11. The heating fluid supplied to the heating nozzle 11 through the heating-fluid supply system 30 is injected onto the polishing surface of the polishing pad 3, thereby heating the polishing surface to a predetermined target temperature.

Hereinafter, with reference to FIG. 7, an example will be described in which the heating fluid supplied from the heating-fluid supply system 30 to the heating nozzle 11 is superheated steam. However, the heating fluid is not limited to this example. The heating fluid may be a gas with high-temperature (e.g., high-temperature air, nitrogen, or argon), or heated steam. Here, the superheated steam refers to high-temperature steam that has obtained by further heating the saturated steam.

Further, the heater 9 described below is a non-contact type heater in which the heating fluid is injected onto the polishing surface of the polishing pad 3 to increase the pad temperature. However, the heater 9 is not limited to this example as long as the heater 9 can increase the pad temperature to the desired target temperature. For example, the heater 9 may be a heater that comes into contact with the polishing surface of the polishing pad 3.

The heating-fluid supply system 30 shown in FIG. 7 includes a superheated-steam generator 31, a superheated-steam supply line 32 extending from the superheated-steam generator 31 to the heating nozzle 11, a water supply line 33 for supplying a water to the superheated-steam generator 31, a gas supply line 34 for supplying a gas at room temperature to the superheated-steam generator 31. The gas supply line 34 extends from a gas supply source (not shown) to the superheated-steam generator 31.

The superheated-steam generator 31 mixes a water supplied from the water supply line 33 and a gas at room temperature supplied from the gas supply line 34 to generate the superheated steam regulated to a predetermined temperature. The superheated steam is supplied to the heating nozzle 11 through the superheated-steam supply line 32, and is injected from the heating nozzle 11 onto the polishing surface of the polishing pad 3. This operation enables the temperature of the polishing surface of the polishing pad 3 to be increased.

The heating-fluid supply system 30 shown in FIG. 7 further includes a flow regulator 35 disposed in the superheated-steam supply line 32, and an exhaust line 36 which branches off from the superheated-steam supply line 32 at an upstream side of the flow regulator 35. The flow regulator 35 enables a flow rate of the superheated steam supplied to the heating nozzle 11 to be controlled. Excess superheated steam is discharged from the polishing apparatus through the exhaust line 36.

The controller 40 is coupled to the superheated steam generator 31 and the flow regulator 35. The controller 40 controls operations of the superheated steam generator 31 and the flow regulator 35 based on the measurement values of the pad-temperature measuring device 10.

When polishing the wafer W with the polishing apparatus configured in this manner, the controller 40 controls operations of the superheated steam generator 31 and the flow regulator 35 based on the measurement values of the pad-temperature measuring device 10 to thereby match the temperature of the polishing surface of the polishing pad 3 (i.e., pad temperature) to a predetermined target temperature. For example, the controller 40 controls operations of the flow regulators 35, 54 to regulate the flow rate of the superheated steam and the flow rate of the cooling gas such that the pad surface temperature matches the predetermined target temperature. More specifically, the controller 40 controls the flow rate of the heating fluid injected from the heating nozzle 11 of the heater 9 and/or the flow rate of the pressure gas containing the cooling agent injected from the cooling nozzles 51 of the cooler 50 to thereby match the pad temperature to the desired temperature. The controller 40, which can perform such control, controls, for example, the operation of the heaters 9 to increase the pad temperature to a first polishing temperature higher than the room temperature, and performs a first polishing of the wafer W. Next, the controller 40 controls at least the operation of the cooler 50 to decrease the pad temperature to a second polishing temperature lower than the first polishing temperature, and performs a second polishing of the wafer W.

Combining the plurality of polishing processes in this manner enables the wafer W to be polished more precisely. According to the polishing apparatus described above, since the pad temperature is decreased by use of the cooling agent having a boiling point lower than atmosphere temperature (or lower than room temperature), the wafer W can be polished at the second polishing temperature that is set lower than atmosphere temperature (or room temperature). In other words, the polishing apparatus described above can polish the wafer W while controlling the pad temperature over a wider temperature control range than conventional polishing apparatus. Further, since the pad temperature can be quickly decreased from the first polishing temperature to the second polishing temperature, the wafer W can be polished more precisely than with conventional polishing apparatus, and the in-plane uniformity of the wafer W after polishing can be improved.

When decreasing the pad temperature from the first polishing temperature to the second polishing temperature, using only the cooler 50 enables the pad temperature to quickly reach the second polishing temperature. On the other hand, the controller 40 can freely control the rate of decrease in pad temperature from the first polishing temperature to the second polishing temperature by using both the cooler 50 and the heater 9.

For example, it is assumed that the controller 40 stores an intermediate temperature set between the first polishing temperature and the second polishing temperature. In this case, the controller 40 controls only the operation of the cooler 50 until the pad temperature reaches the intermediate temperature, thereby quickly decreasing the pad temperature to the intermediate temperature. Next, the controller 40 may control the operations of both the cooler 50 and the heater 9 until the pad temperature reaches the second polishing temperature from the intermediate temperature, thereby gradually reaching the pad temperature to the second polishing temperature. Such control effectively prevents a phenomenon in which the pad temperature significantly falls below the second polishing temperature (so-called hunting phenomenon).

As shown in FIG. 4, when the cooler 50 has the plurality of cooling nozzles 51 and the polishing apparatus has the plurality of pad-temperature measuring devices 10 corresponding to the number of cooling nozzles 51, the controller 40 can independently control each of the pad temperatures in the plurality of regions Z1-Z6 described above (see FIG. 5). When performing such controls, it is preferable that, as described with reference to FIGS. 2 and 3, the cooler 50 has the plurality of cooling-agent flow regulators 55 disposed in each of the cooling-agent branch lines 53b, and that the gas injector 60 has the plurality of dry-gas flow regulators 65 disposed in each of the dry-gas branch lines 63b. The polishing apparatus with such a configuration enables the controller 40 to readily control the flow rate of cooling agent flowing through each of the cooling-agent branch lines 53b and the flow rate of dry gas flowing through each of the dry gas branch lines 63b.

FIG. 8 is a schematic view showing an example of a position adjustment mechanism for adjusting an inclination and a height of the cooling nozzle 51 relative to the polishing pad. The position adjustment mechanism 90 shown in FIG. 8 includes a nozzle bracket 91 coupled to an end of each cooling nozzle 51, a holding bracket 92 to which the nozzle bracket 91 is coupled, and a fastening device 93 for coupling the nozzle bracket 91 to the holding bracket 92.

In this embodiment, the holding bracket 92 is fixed to a stationary member (not shown), such as a beam of the polishing apparatus. Further, the holding bracket 92 has a long hole 92a formed therein. The long hole 92a extends in a direction perpendicular to the polishing surface of the polishing pad 3. In other words, the long hole 92a has a long diameter extending in a direction perpendicular to the polishing surface of the polishing pad 3.

In this embodiment, the fastening device 93 is composed of a bolt and a nut, and the nozzle bracket 91 has a through hole (not shown) into which the bolt of the fastening device 93 can be inserted. The bolt of the fastening device 93 are inserted into both of the through hole of the nozzle bracket 91 and the long hole 92a of the holding bracket 92, and then nut is fastened to that bolt, thereby holding the cooling nozzle 51 to the polishing apparatus via the nozzle bracket 91 and the holding bracket 92.

The nut of the fastening device 93 is loosened and then an angle of the nozzle bracket 91 relative to the holding bracket 92 is changed, so that the inclination of the cooling nozzle 51 relative to the polishing surface of the polishing pad 3 can be changed (adjusted). Further, with the nut of the fastening device 93 loosened, the bolt of the fastening device 93 is moved together with the nozzle bracket 91 within the long hole 92a of the holding bracket 92, so that a vertical position of the cooling nozzle 51 relative to the polishing surface of the polishing pad 3 can be adjusted.

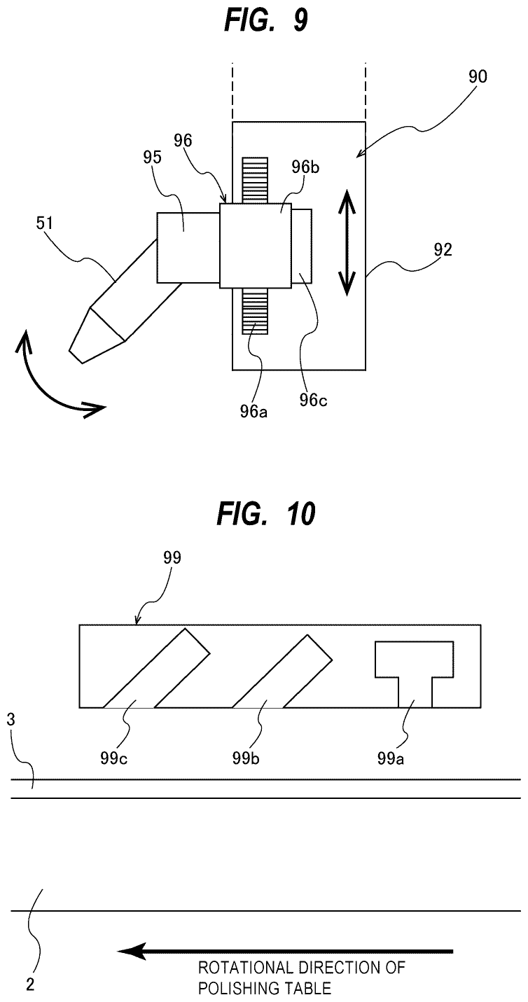

FIG. 9 is a schematic view showing another example of the position adjustment mechanism. The position adjustment mechanism 90 shown in FIG. 9 is composed of a rotation device 95 coupled to the rear end of the cooling nozzle 51, and an up-and-down movement device 96 that couples the rotation device 95 to the holding bracket 92 and moves the cooling nozzle 51 and the rotation device 95 along the holding bracket 92. The rotation device 95 is, for example, a motor (e.g., servo motor or stepping motor) that pivots the cooling nozzle 51 relative to the polishing surface of the polishing pad 3. The up-and-down movement device 96 is composed of, for example, a rail 96a formed in the holding bracket 92, a coupling device 96b for coupling the rotation device 95 to the rail 96a, and a motor (e.g., servo motor or stepping motor) 96c for moving the coupling device 96b along the rail 96a.

The rotation device 95 and the up-and-down movement device 96 in the position adjustment mechanism 90 are coupled to the controller 40, and the controller 40 controls operations of the rotation device 95 and the up-and-down movement device 96. With this configuration, the inclination and the height of the cooling nozzle 51 relative to the polishing surface of the polishing pad 3 can be automatically adjusted.

When the pressure gas containing cooling agent is injected from the cooling nozzle 51 onto the polishing surface of the polishing pad 3, the pressure gas colliding with the polishing surface may cause the polishing liquid on the polishing surface to be scattered. If the polishing liquid is scattered from the polishing surface, there is a risk that the desired polishing rate cannot be achieved, and further, there is a risk that the scattered polishing liquid may contaminate components, such as the polishing table 2, in the polishing apparatus. Therefore, adjusting the inclination and the height of the cooling nozzle 51 relative to the polishing surface of the polishing pad 3 prevents the polishing liquid to be scattered.

As polishing of the wafer W is repeated, the surface of the polishing pad 3 becomes worn, and as a result, the inclination and the height of the cooling nozzle 51 relative to the polishing surface of the polishing pad 3 are gradually changed. Therefore, the position adjustment mechanism 90 preferably has the configuration that, as described with reference to FIG. 9, can automatically adjust the inclination and the height of the cooling nozzle 51 relative to the polishing surface of the polishing pad 3.

FIG. 10 is a schematic view showing a common nozzle formed integrally with the heating nozzle of the heater, the cooling nozzle of the cooler, and the gas nozzle of the gas injector. As shown in FIG. 10, the pad-temperature regulating apparatus 5 may have a common nozzle 99 in which the heating nozzle 11 of the heater 9, the cooling nozzle 51 of the cooler 50, and the dry-gas nozzle 61 of the gas injector 60 are integrated.

The common nozzle 99 has a first discharge port 99a that serves as the heating nozzle 11 described above, a second discharge port 99b that serves as the cooling nozzle 51 described above, and a third discharge port 99c that serves as the dry-gas nozzle 61 described above. The cooling-agent line 53, the dry-gas line 63, and the superheated-steam supply line 32, which are described above, are coupled to the common nozzle 99. Thus the superheated steam is injected from the first discharge port 99a, the pressure gas containing the cooling agent is injected from the second discharge port 99b, and the dry gas is injected from the third discharge port 99c.

When the polishing apparatus has such a common nozzle 99, the cooling nozzle 51 in the common nozzle 99 is located between the heating nozzle 11 and the dry-gas nozzle 61 as viewed in the rotational direction of the polishing table 2. More specifically, the second discharge port 99b is placed between the first discharge port 99a and the third discharge port 99c as viewed in the rotational direction of the polishing table 2. In other words, the second discharge port 99b is placed upstream of the third discharge port 99c in the rotational direction of the polishing table 2, and downstream of the first discharge port 99a in the rotational direction of the polishing table 2.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing apparatus comprising:
a rotatable polishing table supporting a polishing pad;
a polishing head configured to press a substrate against a polishing surface of the rotating polishing pad to polish the substrate;
at least one pad-temperature measuring device configured to measuring a temperature of the polishing surface;
a pad-temperature regulating apparatus for regulating the temperature of the polishing surface; and
a controller configured to control operation of the pad-temperature regulating apparatus based on the temperature of the polishing surface measured by the at least one pad-temperature measuring device,
wherein the pad-temperature regulating apparatus includes:
at least one cooling nozzle configured to inject a cooling agent onto the polishing surface; and
at least one gas nozzle configured to inject dry gas onto the polishing surface, and
the cooling agent has a boiling point lower than atmosphere temperature.

2. The polishing apparatus according to claim 1, wherein the cooling nozzle is placed between the polishing head and the gas nozzle as viewed in a rotational direction of the polishing table.

3. The polishing apparatus according to claim 1, wherein the at least one cooling nozzle comprises a plurality of cooling nozzles arranged in correspondence with each of a plurality of regions divided in a radial direction of the polishing table, and
the controller controls a flow rate of the cooling agent supplied to each cooling nozzle to thereby independently regulate the temperature of each of the plural regions.

4. The polishing apparatus according to claim 3, wherein the at least one pad-temperature measuring device comprises a plurality of pad-temperature measuring devices that can measure the temperatures of the plurality of regions, respectively.

5. The polishing apparatus according to claim 1, wherein the pad-temperature regulating apparatus further comprises a heater configured to heat the polishing surface, and
the heater is placed between the polishing head and the at least one cooling nozzle, as viewed in a rotational direction of the polishing table.

6. The polishing apparatus according to claim 1, wherein the cooling agent is dry ice.
